(19) United States
(12) Patent Application Publication
(10) Pub. No.: US 2026/0085406 A1
(43) Pub. Date: Mar. 26, 2026

(54) JANUS TRANSITION METAL DICHALCOGENIDE MATERIAL, METHOD FOR FABRICATING THEREOF, AND SENSOR

(71) Applicant: NATIONAL TSING HUA UNIVERSITY, HSINCHU (TW)

(72) Inventors: Yu-Lun CHUEH, HSINCHU (TW); Yu-Ren PENG, HSINCHU (TW)

(21) Appl. No.: 18/890,805

(22) Filed: Sep. 20, 2024

(51) Int. Cl. C23C 16/30; C23C 16/50; C23C 16/52

(52) U.S. Cl. CPC C23C 16/305; C23C 16/50; C23C 16/52

(57) ABSTRACT

The present disclosure provides a method for fabricating a Janus transition metal dichalcogenide material that includes performing a heating step, performing a plasma-forming step and performing a depositing step. In the heating step, a chalcogen solid is heated so as to form a chalcogen gas. In the plasma-forming step, a reaction gas is introduced so as to assist the chalcogen gas to form a chalcogen plasma. In the depositing step, a substrate is put near the chalcogen plasma so as to form a Janus transition metal dichalcogenide material.

### BACKGROUND

### Technical Field

The present disclosure relates to a transition metal dichalcogenide material, a method for fabricating thereof, and an application thereof. More particularly, the present disclosure relates to a Janus transition metal dichalcogenide material, a method for fabricating thereof, and a sensor.

### Description of Related Art

As technology rapidly advances, the demand for sensors with a high sensitivity and a high selectivity is growing day by day. Although conventional sensor technologies have been widely applied in many fields, the conventional sensor technologies still face numerous challenges in terms of sensitivity, stability, and miniaturization. Especially in the fields of environmental monitoring, biomedicine, and safety, there is an acute need for sensors capable of rapidly detecting target molecules at low concentrations.

Transition metal dichalcogenides with atomically thick have unique optical properties, and show a potential in surface-enhanced Raman scattering (SERS) applications that become an important means to improve a sensor performance. In order to apply the SERS technology to a high-sensitivity sensing application with low-concentrations molecules, it is necessary to improve an efficiency of Raman signal amplification in sensors.

Therefore, developing a material with a surface-enhanced Raman scattering effect, a high specific surface area, an electronic transporting performance and a chemical stability, and a process that is feasible for a mass production has been the main goal of the industry.

### SUMMARY

According to one aspect of the present disclosure, a method for fabricating a Janus transition metal dichalcogenide material includes performing a heating step, performing a plasma-forming step and performing a depositing step. In the heating step, a chalcogen solid is heated so as to form a chalcogen gas with a heating temperature, and the heating temperature is 170° C. to 900° C. In the plasma-forming step, a reaction gas is introduced so as to assist the chalcogen gas to form a chalcogen plasma with a plasma operating power, the reaction gas includes a hydrogen, a nitrogen, an argon, or a combination thereof, and the plasma operating power is 1 W to 200 W. In the depositing step, a substrate is put near the chalcogen plasma, the substrate includes a base layer and a coating layer, and a deposition reaction is performed between the chalcogen plasma and the coating layer at a reaction temperature and a reaction pressure so as to form a Janus transition metal dichalcogenide material.

According to another aspect of the present disclosure, a Janus transition metal dichalcogenide material is fabricated by the method for fabricating the Janus transition metal dichalcogenide material of the aforementioned aspect, and the Janus transition metal dichalcogenide material includes a transition metal layer, a first chalcogen layer and a second chalcogen layer. The first chalcogen layer is covalently bonded to one side of the transition metal layer, and the second chalcogen layer is covalently bonded to the other side of the transition metal layer.

According to still another aspect of the present disclosure, a sensor includes a substrate and a Raman spectrometer. The substrate includes the Janus transition metal dichalcogenide material of the aforementioned aspect, the Raman spectrometer includes a light emitter and a light receiver, and the substrate is placed between the light emitter and the light receiver.

### BRIEF DESCRIPTION OF THE DRAWINGS

The present disclosure can be more fully understood by reading the following detailed description of the embodiment, with reference made to the accompanying drawings as follows:

FIG. 1 is a flow chart of a method for fabricating a Janus transition metal dichalcogenide material according to one embodiment of the present disclosure.

FIG. 2 is a schematic view of a plasma-assisted chemical vapor reaction system using in the method for fabricating the Janus transition metal dichalcogenide material of the present disclosure.

FIG. 3 is a structural diagram of a Janus transition metal dichalcogenide material according to another embodiment of the present disclosure.

FIG. 4 is a Raman spectrum of the Janus transition metal dichalcogenide materials of Comparative example 1, Example 1, Example 2 and Example 3.

FIG. 5 is sensing Raman scattering signals of different concentrations of crystal violet by a sensor of Example 4.

FIG. 6 is a sensing linearity graph of the different concentrations of crystal violet by the sensor of Example 4.

FIG. 7 is a diagram of sensing Raman scattering signals of different concentrations of ammonium chloride by the sensor of Example 4.

### DETAILED DESCRIPTION

The present disclosure will be further exemplified by the following specific embodiments. However, the embodiments can be applied to various inventive concepts and can be embodied in various specific ways. The specific embodiments are only for the purposes of description, and are not limited to these practical details thereof. In addition, some conventional structures and elements are illustrated in the drawings in a simple and schematic way, and repeated elements can be presented by the same or similar reference numerals.

### Method for Fabricating Janus Transition Metal Dichalcogenide Material

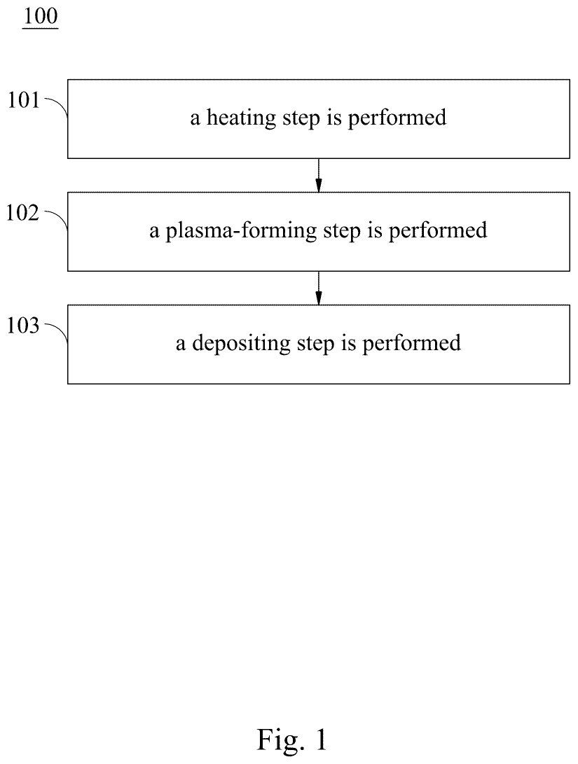

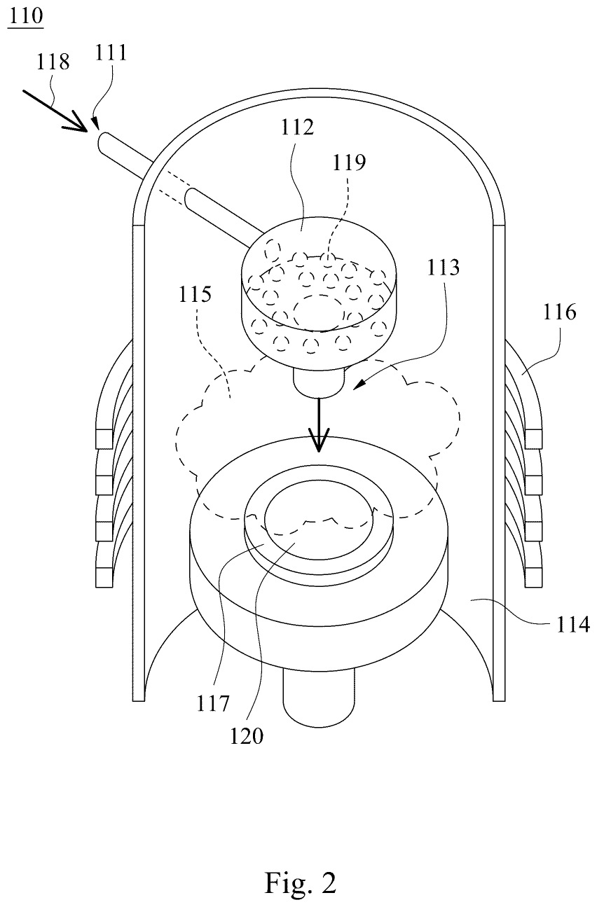

Reference is made to FIG. 1 and FIG. 2, FIG. 1 is a flow chart of a method for fabricating a Janus transition metal dichalcogenide material 100 according to one embodiment of the present disclosure, and FIG. 2 is a schematic view of a plasma-assisted chemical vapor reaction system 110 using in the method for fabricating the Janus transition metal dichalcogenide material 100 of the present disclosure. The method for fabricating the Janus transition metal dichalcogenide material 100 includes step 101, step 102, and step 103.

In step 101, a heating step is performed, and a chalcogen solid 119 is heated so as to form a chalcogen gas (not shown) with a heating temperature, wherein the heating temperature is 170° C. to 900° C. Specifically, the chalcogen solid 119 is heated in a first space 112, and a temperature of the first space 112 is controlled within a range of 170° C. to 900° C. Therefore, the chalcogen solid 119 can be stably transformed into the chalcogen gas.

In step 102, a plasma-forming step is performed, and a reaction gas 118 is introduced so as to assist the chalcogen gas to form a chalcogen plasma 115 with a plasma operating power, wherein the reaction gas 118 includes a hydrogen, a nitrogen, an argon, or a combination thereof, and the plasma operating power is 1 W to 200 W. In detail, the reaction gas 118 enters the first space 112 through a gas inlet 111 and is mixed with the chalcogen gas. Moreover, the reaction gas 118 and the chalcogen gas flow out through a gas outlet 113, enter a second space 114, and correspond to an inductively coupled plasma (ICP) coil 116 to form the chalcogen plasma 115. Preferably, the reaction gas 118 can include the hydrogen. Therefore, a generating efficiency of the chalcogen plasma 115 can be improved. In detail, the reaction gas 118 is the hydrogen and affected by the inductively coupled plasma coil 116, and the reaction gas 118 and the chalcogen gas can be transformed into the chalcogen plasma 115. Furthermore, the chalcogen plasma 115 can be represented as H₂X, wherein H represents hydrogen atom, and X represents a sulfur atom, a selenium atom or a tellurium atom.

Moreover, a flow rate of the reaction gas 118 can be 1 sccm (standard cubic centimeter per minute) to 500 sccm. Therefore, it is favorable for enhancing a mixing uniformity of the reaction gas 118 and the chalcogen gas so as to improve the generating efficiency of the chalcogen plasma 115.

In step 103, a depositing step is performed, and a substrate 117 is put near the chalcogen plasma 115. The substrate 117 includes a base layer and a coating layer, and a deposition reaction is performed between the chalcogen plasma 115 and the coating layer at a reaction temperature and a reaction pressure so as to form a Janus transition metal dichalcogenide material 120. In detail, a Janus transition metal dichalcogenide of the Janus transition metal dichalcogenide material 120 can be an asymmetric transition metal dichalcogenide. Moreover, the reaction temperature can be 10° C. to 600° C., and the reaction pressure can be 0.01 torr to 760 torr. Therefore, the Janus transition metal dichalcogenide material 120 formed at a low temperature can be deposited on a base layer with a low melting point, such as a polyimide (PI), and it is favorable for applying the Janus transition metal dichalcogenide material 120 to a flexible printed circuit. Preferably, the reaction temperature can be 300° C. to 600° C., and it is favorable for enhancing a crystallization of the Janus transition metal dichalcogenide material 120 so as to improve the sensing signal strength of a surface-enhanced Raman scattering sensor.

In detail, in the depositing step, the chalcogen plasma 115 can be dissociated to form a chalcogen-containing precursor H₂X⁺ with a high activity, and it is favorable for a generation of the Janus transition metal dichalcogenide material 120 so that the Janus transition metal dichalcogenide material 120 can be fabricated at a lower reaction temperature, and the production efficiency and the yield of the Janus transition metal dichalcogenide material 120 can be improved. Moreover, as the reaction temperature required for the Janus transition metal dichalcogenide material 120 is decreased, a feasibility of depositing the Janus transition metal dichalcogenide material 120 on the base layer with a low melting point can be expanded. For example, the Janus transition metal dichalcogenide material 120 can be deposited on a flexible base layer, such as polyimide, polyethylene terephthalate (PET), hexagonal boron nitride (h-BN), glass, or mica, and it is favorable for an application and a development of the Janus transition metal dichalcogenide material 120 in electronic products.

Furthermore, as the reaction temperature is larger than 200° C., the Janus transition metal dichalcogenide material 120 with an alloy phase can be fabricated, and the Janus transition metal dichalcogenide material 120 with the alloy phase has stable surface chemical properties. Therefore, it is favorable for improving a sensing sensitivity of the surface-enhanced Raman scattering sensor with the Janus transition metal dichalcogenide material 120.

The coating layer can include a transition metal source and a first chalcogen source, and the chalcogen solid 119 can include a second chalcogen source. The transition metal source can be a molybdenum, a tungsten, a chromium, a platinum, a palladium, a nickel, a copper, a cobalt, a zinc, a manganese, or a titanium. Transition metals are among alkali metals, alkaline earth metals and nonmetals, and most of the transition metals have unfilled valence shell d-orbitals. Therefore, the transition metals can be stably bonded with chalcogens and form transition metal dichalcogenides with special optical properties.

The first chalcogen source can be a sulfur or a selenium. Therefore, it is favorable for a stable chemical bonding in the Janus transition metal dichalcogenide material 120 of the present disclosure. Furthermore, the first chalcogen source can be the sulfur, and the second chalcogen source can be the selenium or a tellurium. The first chalcogen source is different from the second chalcogen source. Therefore, the Janus transition metal dichalcogenide material 120 of the present disclosure has an asymmetric structure that has highly unique surface-chemical and physical properties, especially in the Raman signal enhancement. Therefore, it is favorable for improving an applicability of the surface-enhanced Raman scattering sensor.

Moreover, a thickness of the coating layer can be 1 nm to 30 nm. Therefore, a conversion rate of the Janus transition metal dichalcogenide material 120 fabricated by the method for fabricating the Janus transition metal dichalcogenide material 100 of the present disclosure is better. Further, the thickness of the coating layer can be 1 nm to 10 nm. Therefore, the thickness of the Janus transition metal dichalcogenide material 120 can be thinned, an electron transporting capability of the Janus transition metal dichalcogenide material 120 can be enhanced so as to improve the sensing sensitivity of the surface-enhanced Raman scattering sensor.

Furthermore, the Janus transition metal dichalcogenide of the Janus transition metal dichalcogenide material 120 can be the asymmetric transition metal dichalcogenide. In detail, the method for fabricating the Janus transition metal dichalcogenide material 100 of the present disclosure can be used to grow the Janus transition metal dichalcogenide material 120 with a large wafer-scale on the substrate 117 with a large area. Therefore, a high quality and a material uniformity of the Janus transition metal dichalcogenide material 120 can be ensured, and it is favorable for a commercial-scale production and application.

### Janus Transition Metal Dichalcogenide Material

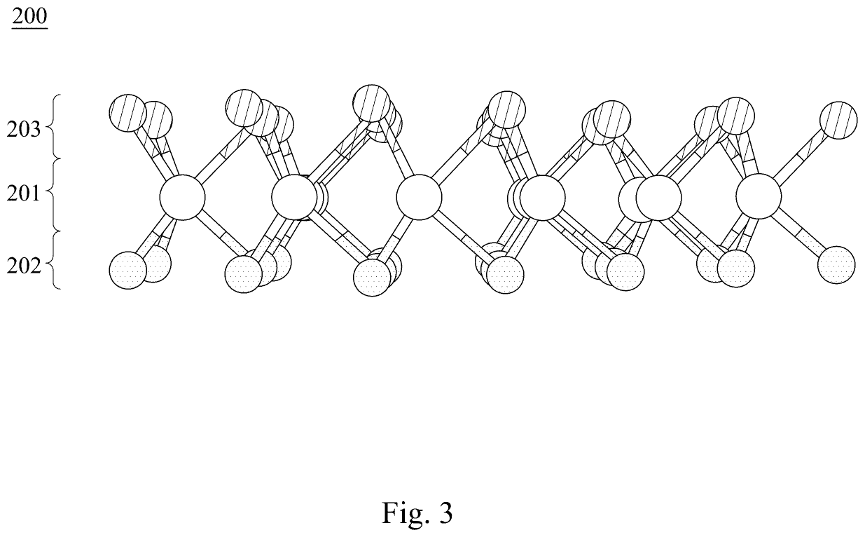

Reference is made to FIG. 3, which is a structural diagram of a Janus transition metal dichalcogenide material 200 according to another embodiment of the present disclosure. The Janus transition metal dichalcogenide material 200 includes a transition metal layer 201, a first chalcogen layer 202 and a second chalcogen layer 203. The first chalcogen layer 202 is covalently bonded to one side of the transition metal layer 201, and the second chalcogen layer 203 is covalently bonded to the other side of the transition metal layer 201. Moreover, the transition metal layer 201 includes the transition metal source, the first chalcogen layer 202 includes the first chalcogen source, and the second chalcogen layer 203 includes the second chalcogen source. The transition metal source can be the molybdenum, the tungsten, the chromium, the platinum, the palladium, the nickel, the copper, the cobalt, the zinc, the manganese, or the titanium. The first chalcogen source can be the sulfur, and the second chalcogen source can be the selenium or the tellurium. Therefore, the Janus transition metal dichalcogenide material 200 has a unique surface properties and an electronic structure, and can be applied in the surface-enhanced Raman scattering technology that is conductive to realize the high-sensitivity sensing application with low-concentrations molecules applications. Further, the Janus transition metal dichalcogenide of the Janus transition metal dichalcogenide material 200 can be the asymmetric transition metal dichalcogenide. Specifically, the asymmetric transition metal dichalcogenide has an excellent molecular adsorption capability and a surface-enhanced Raman scattering effect that is conductive to applications in the sensor field.

### Sensor

Still another aspect of the present disclosure provides a sensor that includes a substrate and a Raman spectrometer. The substrate includes the Janus transition metal dichalcogenide material of the aforementioned aspect, the Raman spectrometer includes a light emitter and a light receiver, and the substrate is placed between the light emitter and the light receiver. Moreover, a sensing light is generated by the light emitter during the sensor sensing, the sensing light passes through the substrate and enters the light receiver, and a sensing signal of the Raman spectrum is generated by the light receiver. Specifically, spectrum data about the molecular structure and vibration properties with the Raman scattering effect of an analyte is measured by the sensor of the present disclosure. The spectral intensity is related to a concentration of the analyte, as the concentration of the analyte is higher, the spectral intensity is larger. Therefore, the analyte is dropped on the substrate during the sensor sensing, and the sensing light passes through the substrate and enters the light receiver, whereby a sensing signal of the Raman spectrum of the analyte can be generated by the light receiver.

The following specific embodiments further illustrate the present disclosure for those with ordinary skill in the technical field to utilize and realize the present disclosure without excessive interpretation. These embodiments should not limit the scope of the present disclosure, but illustrate how to implement the materials and methods of the present disclosure.

### Example 1

The Janus transition metal dichalcogenide material of Example 1 (hereinafter referred to as Example 1) is fabricated by the method for fabricating the Janus transition metal dichalcogenide material that is aforementioned. In detail, in the heating step, the chalcogen solid of Example 1 is a selenium solid, and the selenium solid is heated with the heating temperature of 350° C. to 650° C. so as to form the selenium gas. In the plasma-forming step, the reaction gas is hydrogen, the flow rate of hydrogen is 1 sccm to 200 sccm, and the plasma operating power is 15 W to 100 W. In the depositing step, the base layer is mica, the coating layer is molybdenum disulfide, the reaction temperature is 300° C., the reaction pressure is 0.01 torr to 1 torr. The thickness of the coating layer is 5 nm to 10 nm.

### Example 2

The Janus transition metal dichalcogenide material of Example 2 (hereinafter referred to as Example 2) is fabricated by the method for fabricating the Janus transition metal dichalcogenide material that is similar to Example 1. The difference is the reaction temperature of Example 2 is 400° C.

### Example 3

The Janus transition metal dichalcogenide material of Example 3 (hereinafter referred to as Example 3) is fabricated by the method for fabricating the Janus transition metal dichalcogenide material that is similar to Example 1. The difference is the reaction temperature of Example 3 is 600° C.

### Comparative Example 1

Comparative example 1 is molybdenum disulfide.

### Raman Spectrum Analysis

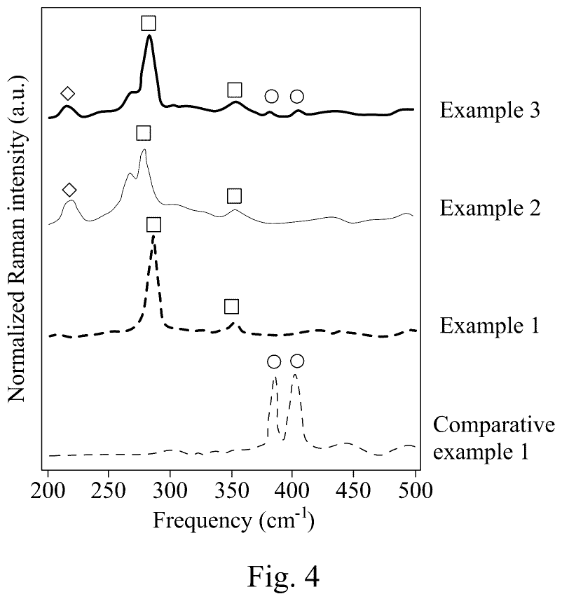

Reference is made to FIG. 4, which is a Raman spectrum of the Janus transition metal dichalcogenide materials of Comparative example 1, Example 1, Example 2 and Example 3. Signals within 385 cm⁻¹ to 405 cm⁻¹ belong to molybdenum disulfide, signals within 289 cm-1 to 355 cm⁻¹ belong to the Janus transition metal dichalcogenide materials, and signals within 270 cm⁻¹ to 307 cm⁻¹ belong to the Janus transition metal dichalcogenide materials with the alloy phase. The signals of the Janus transition metal dichalcogenide materials appear in Example 1 to Example 3, which prove that Example 1 to Example 3 are the Janus transition metal dichalcogenide materials. In the FIG. 4, the signals of the Janus transition metal dichalcogenide materials with the alloy phase appear in Example 2 to Example 3. It can be seen that when the reaction temperature is 400° C. to 600° C. that is conductive to form the Janus transition metal dichalcogenide materials with the alloy phase with stable chemical properties.

### Example 4

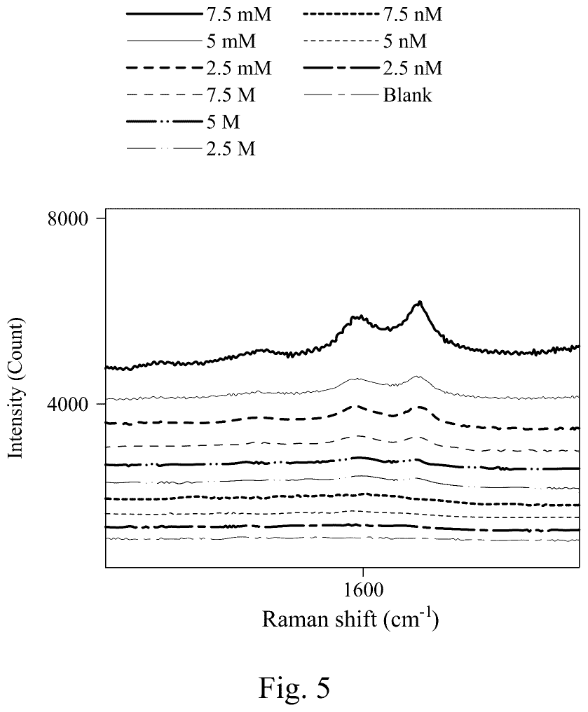

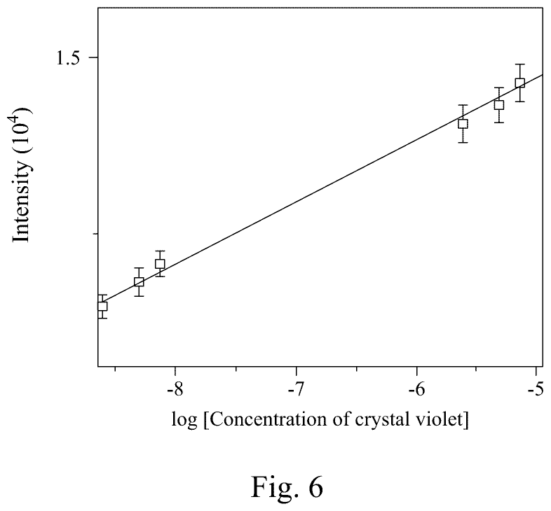

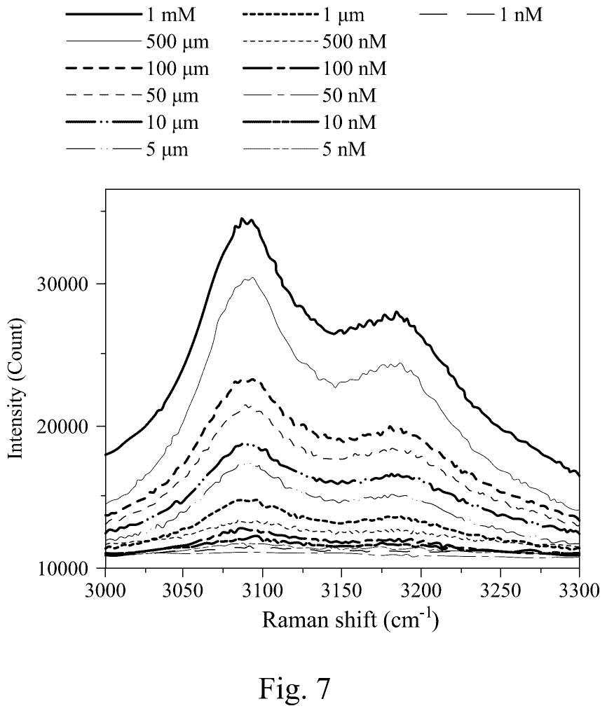

Example 4 is a sensor that includes substrate made of the Janus transition metal dichalcogenide material of Example 1, and with a Raman spectrometer. Reference is made to FIG. 5, FIG. 6 and FIG. 7, FIG. 5 is sensing Raman scattering signals of different concentrations of crystal violet by a sensor of Example 4, FIG. 6 is a sensing linearity graph of the different concentrations of crystal violet by the sensor of Example 4, and FIG. 7 is a diagram of sensing Raman scattering signals of different concentrations of ammonium chloride by the sensor of Example 4.

In a test of sensing crystal violet with different concentrations, an analyte is crystal violet (CV), and a range of the concentrations is 2.5 nM to 7.5 mM (shown in FIG. 5). During conducting the test of sensing crystal violet, solutions of crystal violet with different concentrations are dropped on the Janus transition metal dichalcogenide material of Example 1, and sensing Raman scattering signals are obtained by the Raman spectrometer. In the aforementioned concentration range of crystal violet, as the concentration of crystal violet is higher, a higher Raman scattering signal of crystal violet can be obtained. According to the sensing Raman scattering signals of different concentrations of crystal violet in FIG. 5, the sensing linearity graph in FIG. 6 is illustrated. In FIG. 6, the sensor of the present disclosure shows good sensing linearity with different concentrations of crystal violet, which proves that the Janus transition metal dichalcogenide material of the present disclosure can be applied to a sensor with the surface-enhanced Raman scattering effect.

In a test of sensing ammonium chloride with different concentrations, a concentration range of standard ammonium chloride samples is 1 nM to 1 mM (shown in FIG. 7), and the operating steps are the same as the aforementioned operating steps in the test of sensing crystal violet with different concentrations. During conducting the test of sensing ammonium chloride, solutions of the standard ammonium chloride samples with different concentrations are dropped on the Janus transition metal dichalcogenide material of Example 1, and sensing Raman scattering signals are obtained by the Raman spectrometer. In the aforementioned concentration range of the standard ammonium chloride samples, as the concentration of the standard ammonium chloride samples is higher, a higher Raman scattering signal of the standard ammonium chloride sample can be obtained. In FIG. 7, the sensor of the present disclosure shows significant Raman scattering effects on the standard ammonium chloride samples with different concentrations. As the concentration of the standard ammonium chloride samples increases, the sensing signal of the sensor of the present disclosure increases accordingly.

According to the aforementioned test results, it prove that the Janus transition metal dichalcogenide material and the sensor of the present disclosure has excellent sensing characteristics, and it is favorable for applications of high-sensitive sensors, such as biomedical diagnosis, environmental monitoring, and chemical substance detection.

In conclusion, the Janus transition metal dichalcogenide material of the present disclosure can be fabricated by the method for fabricating the Janus transition metal dichalcogenide material of the present disclosure, and the Janus transition metal dichalcogenide material can be the asymmetric transition metal dichalcogenide material. An asymmetric structure of the asymmetric transition metal dichalcogenide material shows highly unique surface-chemical and physical properties that are beneficial to the adsorption of target molecules. Moreover, special structures and optical properties of the asymmetric structure of the asymmetric transition metal dichalcogenide material can adjust a near field enhancement effect, thereby achieving higher signal enhancement efficiency and a better capability for recognizing molecules. Hence, by applying the Janus transition metal dichalcogenide material of the present disclosure to the sensor, a sensor with high-sensitivity, high-selectivity and high sensing limit can be obtained. Further, the method for fabricating the Janus transition metal dichalcogenide material of the present disclosure can achieve high efficiency and accuracy in the production, and fabricate the Janus transition metal dichalcogenide material with a large wafer-scale and a large area, whereby a high quality and a material uniformity of the Janus transition metal dichalcogenide material can be ensured.

Although the present disclosure has been described in considerable detail with reference to certain embodiments thereof, other embodiments are possible. Therefore, the spirit and scope of the appended claims should not be limited to the description of the embodiments contained herein. In view of the foregoing, it is intended that the present disclosure cover modifications and variations of this disclosure provided they fall within the scope of the following claims.

1. A method for fabricating a Janus transition metal dichalcogenide material, comprising:
performing a heating step, wherein a chalcogen solid is heated so as to form a chalcogen gas with a heating temperature, and the heating temperature is 170° C. to 900° C.;
performing a plasma-forming step, wherein a reaction gas is introduced so as to assist the chalcogen gas to form a chalcogen plasma with a plasma operating power, the reaction gas comprises a hydrogen, a nitrogen, an argon, or a combination thereof, and the plasma operating power is 1 W to 200 W; and
performing a depositing step, wherein a substrate is put near the chalcogen plasma, the substrate comprises a base layer and a coating layer, and a deposition reaction is performed between the chalcogen plasma and the coating layer at a reaction temperature and a reaction pressure so as to form a Janus transition metal dichalcogenide material.

2. The method for fabricating the Janus transition metal dichalcogenide material of claim 1, wherein the coating layer comprises a transition metal source and a first chalcogen source, and the chalcogen solid comprises a second chalcogen source.

3. The method for fabricating the Janus transition metal dichalcogenide material of claim 2, wherein the transition metal source is a molybdenum, a tungsten, a chromium, a platinum, a palladium, a nickel, a copper, a cobalt, a zinc, a manganese, or a titanium.

4. The method for fabricating the Janus transition metal dichalcogenide material of claim 3, wherein the first chalcogen source is a sulfur or a selenium.

5. The method for fabricating the Janus transition metal dichalcogenide material of claim 4, wherein the first chalcogen source is the sulfur, and the second chalcogen source is the selenium or a tellurium.

6. The method for fabricating the Janus transition metal dichalcogenide material of claim 1, wherein the reaction temperature is 10° C. to 600° C., and the reaction pressure is 0.01 torr to 760 torr in the depositing step.

7. The method for fabricating the Janus transition metal dichalcogenide material of claim 1, wherein a thickness of the coating layer is 1 nm to 30 nm.

8. The method for fabricating the Janus transition metal dichalcogenide material of claim 1, wherein a flow rate of the reaction gas is 1 sccm to 500 sccm.

9. A Janus transition metal dichalcogenide material, fabricated by the method for fabricating the Janus transition metal dichalcogenide material of claim 1, the Janus transition metal dichalcogenide material comprising:
a transition metal layer;
a first chalcogen layer, covalently bonded to one side of the transition metal layer; and
a second chalcogen layer, covalently bonded to the other side of the transition metal layer.

10. A sensor, comprising:
a substrate, comprising the Janus transition metal dichalcogenide material of claim 9; and
a Raman spectrometer, comprising a light emitter and a light receiver, and the substrate is placed between the light emitter and the light receiver.
